(19) United States
(12) Patent Application Publication
(10) Pub. No.: US 2026/0223680 A1
(43) Pub. Date: Jul. 30, 2026

(54) CIRCUIT BOARD AND SEMICONDUCTOR PACKAGE COMPRISING SAME

(71) Applicant: LG INNOTEK CO., LTD., Seoul (KR)

(72) Inventors: Bung Suek Oh, Seoul (KR); Yun Ho AN, Seoul (KR)

(73) Assignee: LG INNOTEK CO., LTD., Seoul (KR)

(21) Appl. No.: 19/148,444

(22) PCT Filed: Jan. 22, 2024
(86) PCT No.: PCT/KR2024/001007

§ 371 Date: Jul. 16, 2025

(30) Foreign Application Priority Data
Jan. 20, 2023 (KR) 10-2023-0008835

(51) Int. Cl. H10W 42/00; H10W 70/62

(52) U.S. Cl. CPC H10W 42/121; H10W 70/62

(57) ABSTRACT

A circuit board according to an embodiment includes an insulating layer; and an electrode part disposed on the insulating layer, wherein an upper surface of the electrode part includes a first portion extending along a first direction parallel to an upper surface of the insulating layer, a second portion extending along a second direction parallel to the upper surface of the insulating layer and having a predetermined incline with the first direction, and a bending portion provided between the first portion and the second portion, and wherein the bending portion further includes a reinforcing pattern in a region where an extension line of the first portion and an extension line of the second portion form an obtuse angle.

### TECHNICAL FIELD

An embodiment relates to a circuit board, and more particularly, to a circuit board including an electrode part having improved electrical reliability, and a semiconductor package including the same.

### BACKGROUND ART

As performances of electric/electronic products progresses, technologies for disposing a greater number of semiconductor devices on a semiconductor package circuit board of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

Due to these advantages, the semiconductor package as described above is widely applied to mobile devices, etc.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, a package substrate and/or interposer applied to a semiconductor package may include an electrode part electrically connected to a semiconductor device and/or a semiconductor chiplet. The electrode part may include a plurality of first electrodes corresponding to pads connected to the semiconductor device and/or the semiconductor chiplet, and a plurality of second electrodes corresponding to traces connecting between the plurality of first electrodes. Meanwhile, the number of terminals provided on the semiconductor device and/or the semiconductor chiplet is increasing, or the widths and/or pitches of the terminals are becoming finer. Accordingly, the widths and/or pitches of each of the first electrodes and the second electrodes of the electrode part are also becoming finer.

At this time, as the widths and/or pitches of the plurality of second electrodes become finer, an electrical open problem may occur in which a circuit connection is disconnected at a specific portion of the plurality of second electrodes. For example, the plurality of second electrodes may include a portion that is bent in a horizontal direction and may be extended. In addition, as the widths of the second electrodes become finer, plating defects may occur at the bending portion, and an electrical open problem may occur due to this. Furthermore, when the width and spacing of the second electrode are made smaller and an impact is applied to a bending portion of the second electrode, a crack may occur in the bending portion of the second electrode.

### DISCLOSURE

### Technical Problem

The embodiment provides a circuit board including an electrode part with improved electrical reliability and physical reliability, and a semiconductor package including the same.

In addition, the embodiment provides a circuit board having a reinforcing portion having a step structure in a bending portion of a connection electrode, and a semiconductor package including the same.

In addition, the embodiment provides a circuit board with improved impedance matching characteristics, and a semiconductor package including the same.

In addition, the embodiment provides a circuit board with improved adhesion between an insulating layer and an electrode part, and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; and an electrode part disposed on the insulating layer, wherein an upper surface of the electrode part includes a first portion extending along a first direction parallel to an upper surface of the insulating layer, a second portion extending along a second direction parallel to the upper surface of the insulating layer and having a predetermined incline with the first direction, and a bending portion provided between the first portion and the second portion, and the bending portion further includes a reinforcing pattern in a region where an extension line of the first portion and an extension line of the second portion form an obtuse angle.

In addition, the electrode part has a step whose width changes in the bending portion between the first portion and the second portion.

In addition, a width of the bending portion including the reinforcing pattern is larger than a width of at least one of the first portion and the second portion.

In addition, the electrode part has a width in a range of 2 μm to 8 μm.

In addition, the circuit board further comprises a pad part disposed on the insulating layer and connected to the electrode part.

In addition, the bending portion includes a first side surface facing an outer surface of the pad part, and a second side surface opposite to the first side surface, and the reinforcing pattern is provided on the first side surface of the bending portion.

In addition, the reinforcing pattern is a convex portion that is convex from the first side surface of the bending portion toward the pad part.

In addition, the bending portion further includes a first concave portion that is provided on the second side surface and is concave toward the first side surface.

In addition, at least one side surface of the first portion and the second portion of the electrode part is provided with a second concave portion that is concave toward an inside of the electrode part.

In addition, the electrode part includes a first group of electrode parts including a plurality of electrode patterns spaced apart from each other with a first spacing, and a second group of electrode parts including a plurality of electrode patterns spaced apart from each other with a second spacing larger than the first spacing, the bending portion of the electrode part of the first group is provided with the reinforcing pattern, and the bending portion of the electrode part of the second group is not provided with the reinforcing pattern.

In addition, the electrode part includes a connection portion provided between the pad part and the first portion or the second portion, and the connection portion has a width that changes from the pad part toward the first portion or the second portion.

In addition, the connection portion has a width that gradually decreases from the pad part toward the first portion or the second portion.

In addition, a planar shape of the pad part has an oval shape.

In addition, a perimeter of an upper surface of the pad part includes a curve portion having a specific radius of curvature; a first straight portion connected to the curve portion; and a second straight portion extending along a horizontal direction having a predetermined incline from the first straight portion.

In addition, the insulating layer includes a first insulating layer; and a second insulating layer on the first insulating layer, and the electrode part is provided between the first insulating layer and the second insulating layer, and the second insulating layer covers the reinforcing pattern of the bending portion.

Meanwhile, a circuit board according to an embodiment includes an insulating layer; and an electrode part disposed on the insulating layer, wherein the electrode part includes a first portion extending along a first direction parallel to an upper surface of the insulating layer, a second portion extending along a second direction parallel to an upper surface of the insulating layer and having a predetermined incline with respect to the first direction, and a bending portion provided between the first portion and the second portion, wherein the bending portion includes a first side surface and a second side surface opposite to the first side surface, and the first side surface of the bending portion has a convex portion convex toward an outward direction away from the first side surface, and the second side surface of the bending portion has a concave portion concave toward the first side surface.

In addition, the circuit board further comprises a pad part disposed on the insulating layer, wherein the pad part includes a first group of pad parts including a plurality of pads spaced apart in a third direction that is parallel to the upper surface of the insulating layer and perpendicular to the first direction; and a second group of pad parts including a plurality of pads spaced apart from the first group of pad parts in the first direction and spaced apart in the third direction.

In addition, the electrode part includes a first electrode part provided between the plurality of pads of the pad part of the first group; and a second electrode part provided between the plurality of pads of the pad part of the second group, wherein each of the first and second electrode parts includes a plurality of electrode lines spaced apart from each other in the third direction, and a number of electrode lines of the first electrode part is different from a number of electrode lines of the second electrode part.

In addition, the number of electrode lines of the first electrode part is greater than the number of electrode lines of the second electrode part, and a convex portion is provided on a first side surface of the first electrode part facing the pad part of the first group, and the concave portion is provided on a second side surface of the first electrode part facing the pad part of the second group.

In addition, the concave portion and the convex portion are not provided on first and second side surfaces of the bending portion of the second electrode part.

### Advantageous Effects

The circuit board of the embodiment and the semiconductor package including the same include an electrode part. At this time, an upper surface of the electrode part includes a first portion extended along a first horizontal direction, a second portion extended along a second horizontal direction having a predetermined incline with the first horizontal direction, and a bending portion provided between the first portion and the second portion. At this time, the bending portion includes a reinforcing pattern. The reinforcing pattern can have a function of increasing a width of the bending portion of the electrode part.

The reinforcing pattern is provided with a convex shape toward an adjacent pad. Accordingly, the embodiment can provide the reinforcing pattern with a convex shape, thereby alleviating a phenomenon of current concentration in the bending portion. Accordingly, the embodiment can maintain the current distribution of the electrode part more evenly. In addition, when the convex shape of the reinforcing pattern has a curvature, a pattern can be formed more easily in an exposure process for forming the reinforcing pattern, thereby improving the product yield.

Furthermore, the embodiment can provide a reinforcing pattern in the bending portion, thereby improving a weak rigidity in the bending portion of the electrode part. Therefore, the embodiment can solve an electrical open or crack problem occurring in the bending portion of the electrode part, thereby improving the electrical reliability and/or physical reliability of the semiconductor package. In addition, the embodiment can enable a semiconductor device provided in the semiconductor package to operate smoothly, thereby improving the operational reliability of an electronic product such as a server to which the semiconductor package is applied.

In addition, the electrode part of the embodiment can include a bending portion, thereby improving the integration degree of the electrode part, and shortening an electrical length of the electrode part. Therefore, the embodiment can reduce parasitic capacitance, parasitic inductance, parasitic resistance, etc. of the electrode part, thereby efficiently improving the overall impedance of the electrode part, and further miniaturizing an area of the semiconductor package.

In addition, the electrode part of the embodiment has first and second side surfaces. In addition, the first side surface of the electrode part may be provided with a convex portion of a reinforcing pattern, and the second side surface may be provided with a concave portion. The concave portion may be provided concavely from the second side surface of the electrode part toward the first side surface. The concave portion may alleviate electrical characteristics of the electrode part that change due to the convex portion. Through this, the embodiment may further improve the electrical reliability of the electrode part. For example, the electrode part of the embodiment may have a reduced width in a region including the concave portion. Through this, the embodiment may efficiently improve an impedance of the electrode part, and through this, may function to improve the overall electrical characteristics of the electrode part.

In addition, the electrode part of the embodiment may be provided with a concave portion and a convex portion, and through this, a contact area between the insulating layer and the electrode part may be increased. Through this, the embodiment may improve an adhesion between the electrode part and the insulating layer, and may solve a problem of the electrode part being peeled off from the insulating layer. For example, the concave portion and/or the convex portion of the electrode part may overlap with the insulating layer in a vertical direction and/or a horizontal direction, thereby strengthening a bonding strength in the vertical direction and/or a bonding strength in the horizontal direction between the electrode part and the insulating layer. Furthermore, when each layer of the insulating layer is formed of a different insulating material, peeling in the vertical direction and/or the horizontal direction may occur due to different coefficients of thermal expansion between the different materials. Therefore, the embodiment can improve the electrical reliability of the electrode part by using the concave portion and the convex portion, while improving the mechanical reliability by increasing a contact area with the insulating layer.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view showing a circuit board according to a first embodiment.

FIG. 3 is a cross-sectional view showing a circuit board according to a second embodiment.

FIG. 4 is an enlarged plan view of a partial region of FIG. 2 or FIG. 3 according to a first embodiment.

FIG. 5 is an enlarged plan view of a partial region of FIG. 2 or FIG. 3 according to a second embodiment.

FIG. 6 is an enlarged plan view of a partial region of FIG. 2 or FIG. 3 according to a third embodiment.

FIG. 7 is an enlarged plan view of a partial region of FIG. 2 or FIG. 3 according to a fourth embodiment.

FIG. 8 is an enlarged plan view of a partial region of FIG. 2 or FIG. 3 according to a fifth embodiment.

FIG. 9 is an enlarged plan view of a partial region of FIG. 2 or FIG. 3 according to a sixth embodiment.

FIG. 10 is an enlarged plan view of a partial region of FIG. 2 or FIG. 3 according to a seventh embodiment.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, the circuit board in one embodiment is a first circuit board described below. In addition, the circuit board in another embodiment is a second circuit board described below.

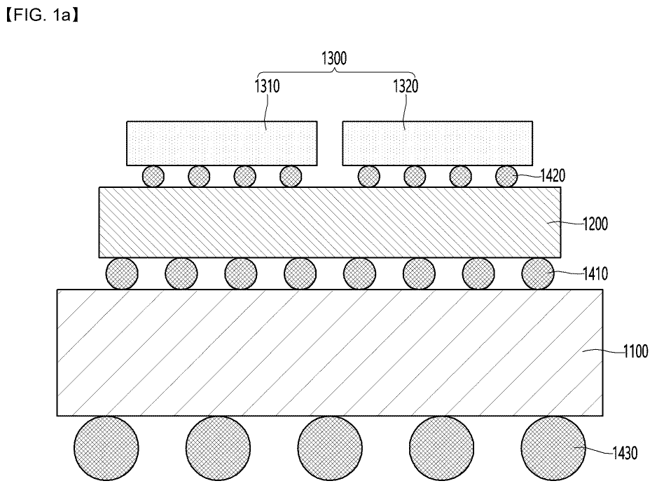

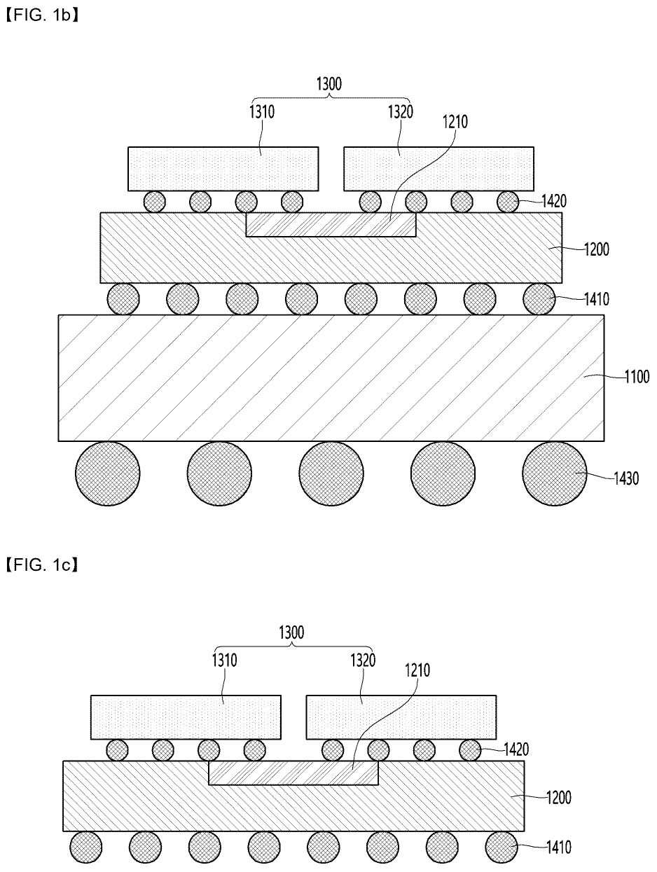

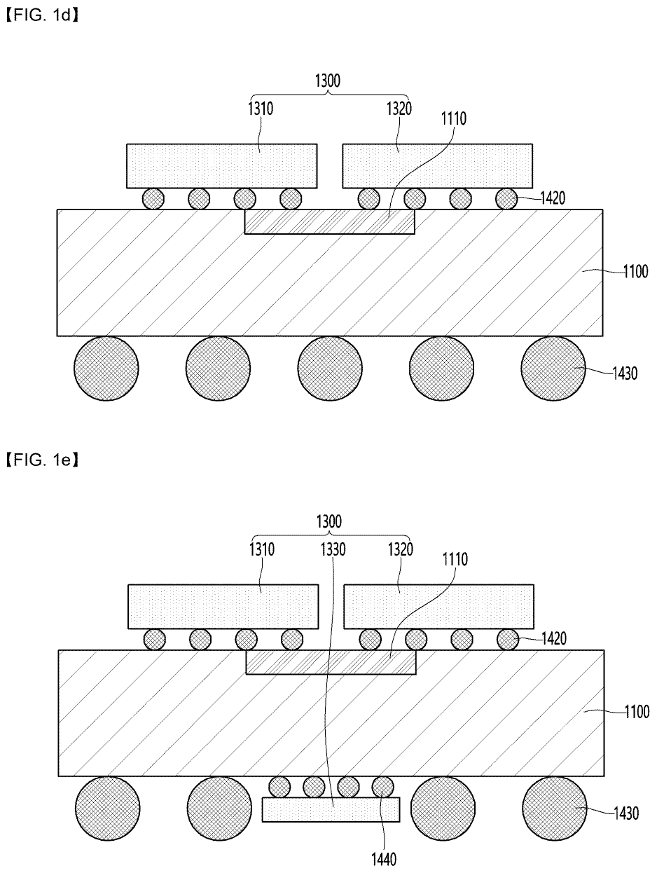

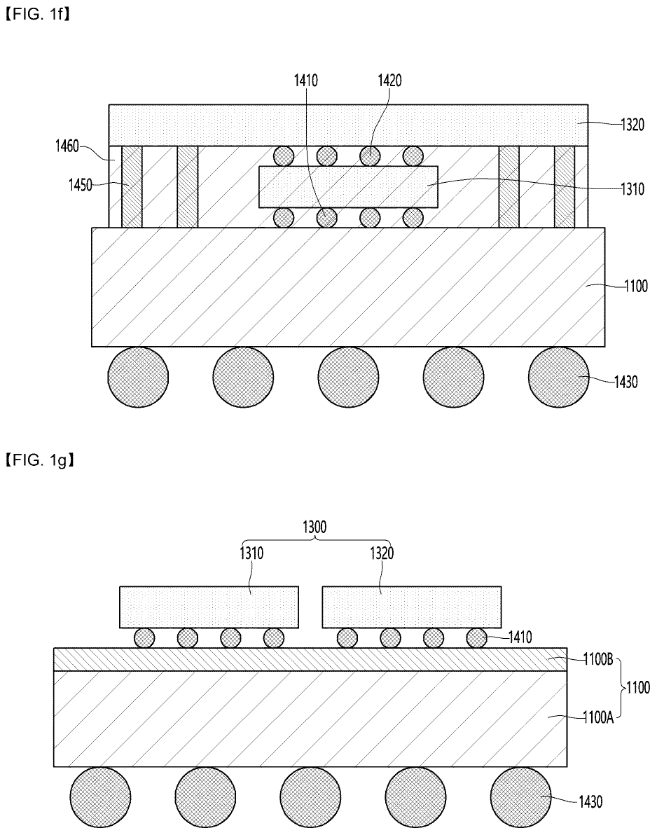

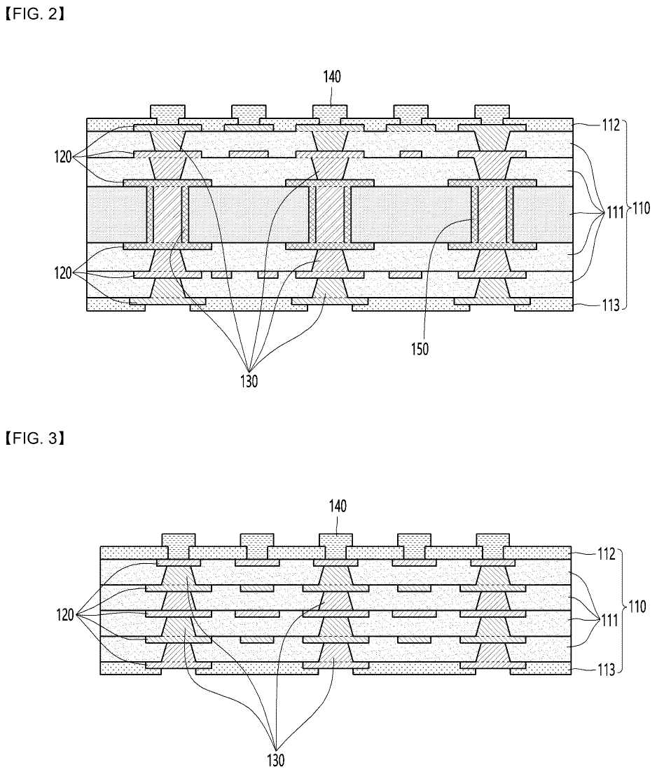

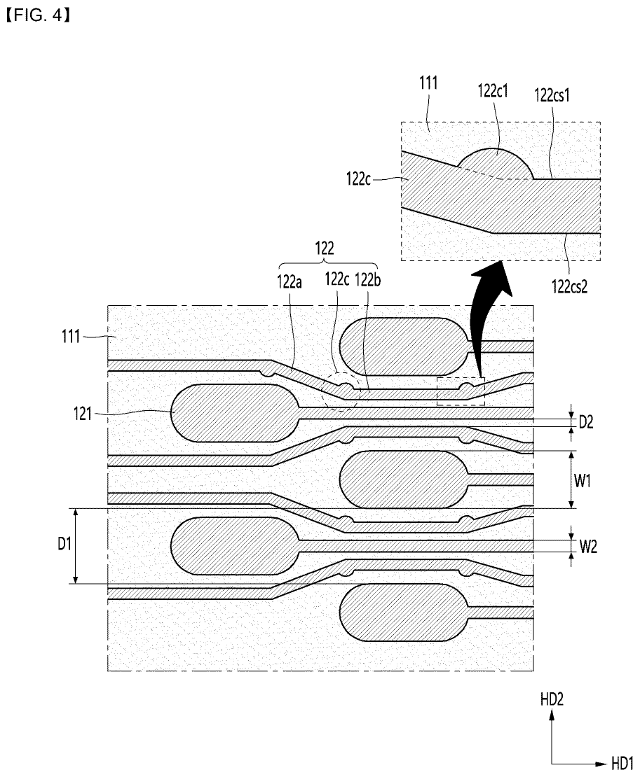

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment includes a first circuit board 1100, a second circuit board 1200, and a semiconductor device 1300.

The first circuit board 1100 means a package substrate.

For example, the first circuit board 1100 provides a space to which at least one external circuit board is coupled. In one embodiment, an external circuit board means a second circuit board 1200 coupled to the first circuit board 1100. Also, the external circuit board in another embodiment means a main board included in an electronic device coupled to a lower portion of the first circuit board 1100.

Also, although not shown in the drawing, the first circuit board 1100 provides a space in which at least one semiconductor device is mounted.

The first circuit board 1100 includes at least one insulating layer, an electrode part disposed on the at least one insulating layer.

A second circuit board 1200 is disposed on the first circuit board 1100.

The second circuit board 1200 may be an interposer. For example, the second circuit board 1200 provides a space in which at least one semiconductor device is mounted. The second circuit board 1200 is connected to the at least one semiconductor device 1300. For example, the second circuit board 1200 provides a space in which the first semiconductor device 1310 and the second semiconductor device 1320 are mounted. The second circuit board 1200 electrically connects the first and second semiconductor devices 1310 and 1320 and the first circuit board 1100 while electrically connecting the first semiconductor device 1310 and the second semiconductor device 1320. That is, the second circuit board 1200 performs a horizontal connection function between a plurality of semiconductor devices and a vertical connection function between the semiconductor devices and the package substrate.

FIG. 1a illustrates that the first and second semiconductor devices 1310 and 1320 are disposed on the second circuit board 1200, but is not limited thereto. In one embodiment, one semiconductor device is disposed on the second circuit board 1200. In another embodiment, three or more semiconductor devices may be disposed.

The second circuit board 1200 is disposed between at least one semiconductor device 1300 and the first circuit board 1100.

In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IoT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment includes a connection part.

The semiconductor package includes a first connection part 1410 disposed between the first circuit board 1100 and the second circuit board 1200. The first connection part 1410 electrically connects the second circuit board 1200 to the first circuit board 1100 while coupling them.

The semiconductor package includes the second connection part 1420 disposed between the second circuit board 1200 and the semiconductor device 1300. The second connection part 1420 electrically connects the semiconductor device 1300 to the second circuit board 1200 while coupling them.

The semiconductor package includes a third connection part 1430 disposed on a lower surface of the first circuit board 1100. The third connection part 1430 electrically connects the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connection part 1420. In this case, the second connection part 1420 may mean a metal layer formed between a plurality of components by the recrystallization.

The first connection part 1410, the second connection part 1420, and the third connection part 1430 may couple a plurality of components to each other by a thermal compression (TC) bonding method. The thermal compression bonding may refer to a method of directly coupling a plurality of components by applying heat and pressure to the first connection part 1410, the second connection part 1420, and the third connection part 1430.

At this time, at least one of the first circuit board 1100 and the second circuit board 1200 may be provided with a protrusion that protrudes outwardly away from the insulating layer of the corresponding board, on which the first connection part 1410, the second connection part 1420, and the third connection part 1430 are disposed. The protrusion may protrude outwardly from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, as the pitch of the terminals of the semiconductor device 1300 becomes finer, a short circuit may occur between the plurality of second connection parts 1420 that are respectively connected to the plurality of terminals of the semiconductor device 1300 by a conductive adhesive such as a solder. Therefore, in the embodiment, thermal compression bonding may be performed to reduce a volume of the second connection part 1420. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connection part 1420 is disposed.

Meanwhile, referring to FIG. 1b, the semiconductor package of the second embodiment may differ from the semiconductor package of the first embodiment in that the connection member 1210 is disposed on the second circuit board 1200. The connection member 1210 may be referred to as a bridge circuit board. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 1210 may be an inorganic bridge. For example, the inorganic bridge may be a silicon bridge. That is, the connection member 1210 may include a silicon circuit board and a redistribution layer disposed on the silicon circuit board.

In another embodiment, the connection member 1210 may be an organic bridge. For example, the connection member 1210 may include an organic material. For example, the connection member 1210 may include an organic circuit board including an organic material instead of the silicon circuit board.

The connection member 1210 may be embedded in the second circuit board 1200, but is not limited thereto. For example, the connection member 1210 may be disposed on the second circuit board 1200 to have a protruding structure.

Also, the second circuit board 1200 may include a cavity, and the connection member 1210 may be disposed in the cavity of the second circuit board 1200.

The connection member 1210 horizontally connects a plurality of semiconductor devices disposed on the second circuit board 1200.

Referring to FIG. 1c, the semiconductor package according to the third embodiment includes a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 1d, the semiconductor package according to the fourth embodiment includes a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment can function as a package circuit board while also performing the function of connecting the semiconductor device 1300 and a main board. To this end, the first circuit board 1100 includes a connection member 1110 for connecting the plurality of semiconductor devices. The connection member 1110 may be an inorganic bridge or an organic material bridge connecting a plurality of semiconductor devices.

Referring to FIG. 1e, the semiconductor package of the fifth embodiment further includes a third semiconductor device 1330 compared to the semiconductor package of the fourth embodiment.

To this end, a fourth connection part 1440 is disposed on the lower surface of the first circuit board 1100.

In addition, a third semiconductor device 1330 is disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1c.

Referring to FIG. 1f, the semiconductor package according to the sixth embodiment includes a first circuit board 1100. A first semiconductor device 1310 is disposed on the first circuit board 1100. To this end, a first connection part 1410 is disposed between the first circuit board 1100 and the first semiconductor device 1310.

In addition, the first circuit board 1100 includes a conductive coupling portion 1450. The conductive coupling portion 1450 further protrudes from the first circuit board 1100 toward the second semiconductor device 1320. The conductive coupling portion 1450 may be referred to as a bump or, alternatively, may also be referred to as a post. The conductive coupling portion 1450 is disposed to have a protruding structure on an electrode disposed on an uppermost side of the first circuit board 1100.

A second semiconductor device 1320 is disposed on the conductive coupling portion 1450. In this case, the second semiconductor device 1320 is connected to the first circuit board 1100 through the conductive coupling portion 1450. In addition, a second connection part 1420 is disposed on the first semiconductor device 1310 and the second semiconductor device 1320.

Accordingly, the second semiconductor device 1320 is electrically connected to the first semiconductor device 1310 through the second connection part 1420.

That is, the second semiconductor device 1320 may be connected to the first circuit board 1100 through the conductive coupling portion 1450, and may be also connected to the first semiconductor device 1310 through the second connection part 1420.

In this case, the second semiconductor device 1320 may receive a power signal and/or electric power through the conductive coupling portion 1450. Also, the second semiconductor device 1320 may transmit and receive a communication signal to and from the first semiconductor device 1310 through the second connection part 1420.

The semiconductor package according to the sixth embodiment may provide a power signal and/or electric power to the second semiconductor device 1320 through the conductive coupling portion 1450, thereby providing sufficient power for driving the second semiconductor device 1320 or enabling smooth control of a power operation.

Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal, an electric power, and a communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package circuit boards are stacked and may be disposed on the first circuit board 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment includes a molding member 1460. The molding member 1460 is disposed between the first circuit board 1100 and the second semiconductor device 1320. For example, the molding member 1460 molds the first connecting member 1410, the second connecting member 1420, the first semiconductor device 1310, and the conductive coupling portion 1450.

Referring to FIG. 1g, the semiconductor package according to the seventh embodiment includes a first circuit board 1100, a first connection part 1410, a first connection part 1410, a semiconductor device 1300, and a third connection part 1430.

In this case, the semiconductor package of the seventh embodiment may differ from the semiconductor package of the fourth embodiment in that the first circuit board 1100 includes a plurality of circuit board layers while the connection member 1110 is omitted.

The first circuit board 1100 includes a plurality of circuit board layers. For example, the first circuit board 1100 includes a first circuit board layer 1100A corresponding to a package substrate and a second circuit board layer 1100B corresponding to the connection member.

In other words, the semiconductor package of the seventh embodiment includes a first circuit board layer 1100A and a second circuit board layer 1100B in which the first circuit board (package circuit board, 1100) and the second circuit board (interposer, 1200) disclosed in FIG. 1a are integrally formed. A material of the insulating layer of the second circuit board layer 1100B is different from a material of an insulating layer of the first circuit board layer 1100A. For example, the material of an insulating layer of the second circuit board layer 1100B may include a photocurable material. For example, the second circuit board layer 1100B may be a photo imageable dielectric (PID). In addition, since the second circuit board layer 1100B includes a photocurable material, it is possible to miniaturize the electrode. Accordingly, in the seventh embodiment, the second circuit board layer 1100B may be formed by sequentially stacking an insulating layer of a photo-curable material on the first circuit board layer 1100A and forming a miniaturized electrode on the insulating layer of the photo-curable material. Accordingly, the second circuit board layer 1100B may include a redistribution layer function including a micro-electrode and may include a function of horizontally connecting a plurality of semiconductor devices 1310 and 1320.

Before describing the circuit board of the embodiment, the circuit board described below may mean any one of the circuit boards included in the previous semiconductor package. For example, the circuit board described below may mean any one of the first circuit board 1100 and the second circuit board 1200 included in the semiconductor package of the first to seventh embodiments.

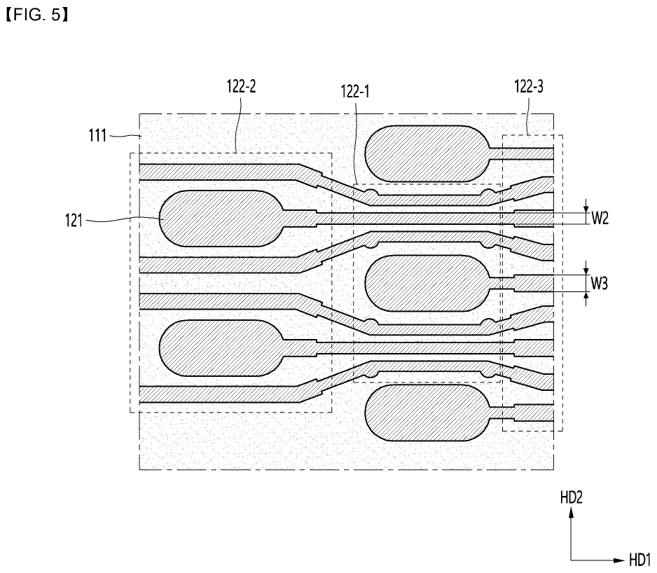

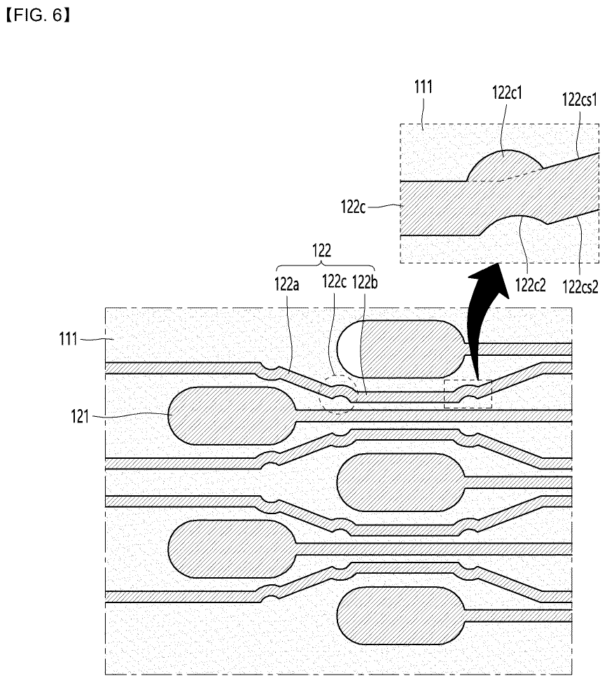

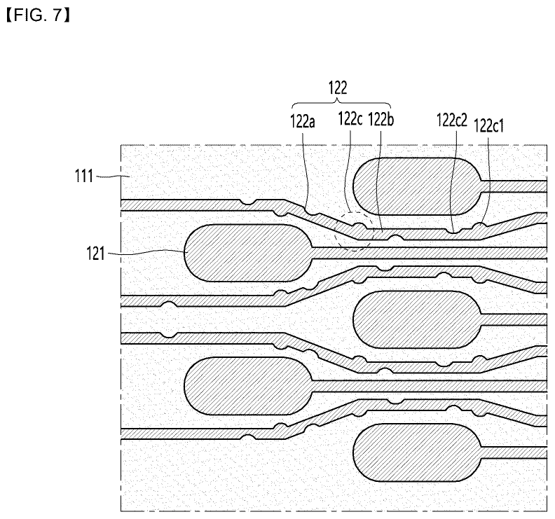

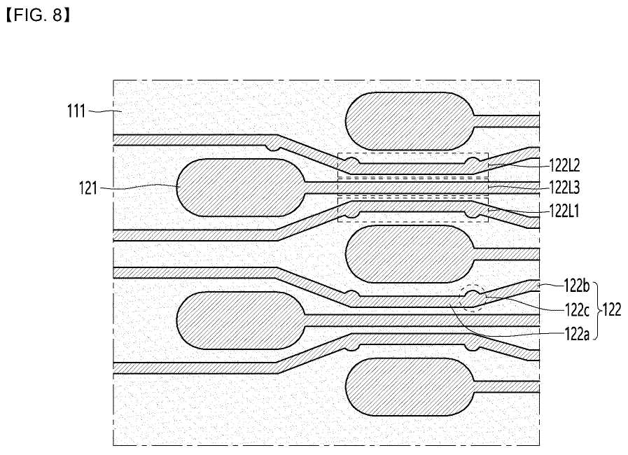

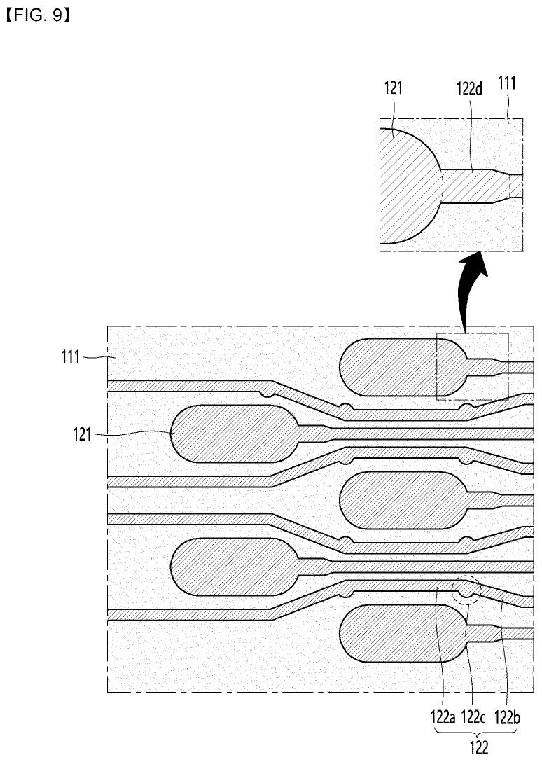

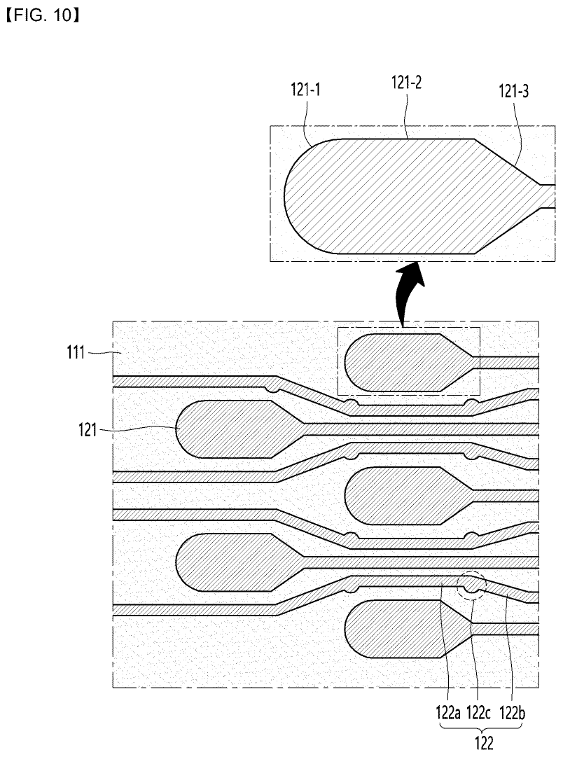

FIG. 2 is a cross-sectional view showing a circuit board according to a first embodiment, FIG. 3 is a cross-sectional view showing a circuit board according to a second embodiment, FIG. 4 is an enlarged plan view of a partial region of FIG. 2 or FIG. 3 according to a first embodiment, FIG. 5 is an enlarged plan view of a partial region of FIG. 2 or FIG. 3 according to a second embodiment, FIG. 6 is an enlarged plan view of a partial region of FIG. 2 or FIG. 3 according to a third embodiment, FIG. 7 is an enlarged plan view of a partial region of FIG. 2 or FIG. 3 according to a fourth embodiment, FIG. 8 is an enlarged plan view of a partial region of FIG. 2 or FIG. 3 according to a fifth embodiment, FIG. 9 is an enlarged plan view of a partial region of FIG. 2 or FIG. 3 according to a sixth embodiment, and FIG. 10 is an enlarged plan view of a partial region of FIG. 2 or FIG. 3 according to a seventh embodiment.

Hereinafter, a circuit board provided in a semiconductor package according to an embodiment will be specifically described with reference to attached drawings.

Referring to FIGS. 2 and 3, a circuit board of the embodiment includes an insulating layer 110 and an electrode part 160.

The insulating layer 110 includes a plurality of layers. The insulating layer 110 includes a first insulating layer 111, a second insulating layer 112, and a third insulating layer 113. The first insulating layer 111 may constitute an inner layer of the insulating layer 110. The term “constituting an inner layer” may mean that at least one insulating layer (e.g., a second insulating layer and a third insulating layer) is disposed above and below the first insulating layer 111.

The second insulating layer 112 is disposed on the first insulating layer 111. For example, the second insulating layer 112 may mean an insulating layer disposed at an uppermost side of the circuit board. The second insulating layer 112 can have a function of protecting an upper surface of the first insulating layer 111, and thus can be referred to as a “first protective layer.”

The third insulating layer 113 is disposed below the first insulating layer 111. For example, the third insulating layer 113 can mean an insulating layer disposed at the lowest side of the substrate. The third insulating layer 113 can have the function of protecting the lower surface of the first insulating layer 111, and thus can be referred to as a “second protective layer.”

The first insulating layer 111 of the circuit board can have a layer structure of at least one layer. Preferably, the first insulating layer 111 of the circuit board can have a plurality of laminated structures. The laminated structures can be distinguished by the electrode part. For example, the electrode part can include a first electrode part 120 and a second electrode part 130. The first electrode part 120 may be provided in a plurality of units and spaced apart from each other in a vertical direction. For example, the first electrode part 120 may include an upper electrode part disposed on the first insulating layer 111 and a lower electrode part disposed under the first insulating layer 111. The upper electrode part and the lower electrode part may be spaced apart from each other in the vertical direction. The second electrode part 130 may be provided between a plurality of first electrode parts. The second electrode part 130 may be provided to penetrate at least a portion of a region of the first insulating layer 111 in the vertical direction. The second electrode part 130 may have a width in a horizontal direction that is different from a width in the horizontal direction of the first electrode part 120. In addition, the second electrode part 130 may have a thickness in the vertical direction that is different from a thickness in the vertical direction of the first electrode part 120. In addition, the second electrode part 130 may have a vertical cross-sectional shape different from a vertical cross-sectional shape of the first electrode part 120. Therefore, the laminated structure of the first insulating layer 111 may be distinguished based on at least one of the difference in width, thickness, and vertical cross-sectional shape between the first electrode part 120 and the second electrode part 130. The circuit board of the embodiment may electrically and efficiently connect at least one semiconductor device and/or the second circuit board to the main board through the laminated structure described above.

Meanwhile, the first insulating layer 111 of the circuit board of FIG. 2 is illustrated as having a five-layer structure, but is not limited thereto. For example, the first insulating layer 111 of the circuit board may have a four-layer structure as illustrated in FIG. 3. In addition, the first insulating layer 111 of another embodiment may have a laminated structure of three layers or less. In addition, the first insulating layer 111 of another embodiment may have a laminated structure of six layers or more.

When the multiple layers of the first insulating layer 111 include a same insulating material, an interface between the multiple layers may not be distinguished. In this case, the laminated structure may be distinguished by the first electrode part 120 and the second electrode part 130.

Meanwhile, when the first insulating layer 111 of the circuit board has a multiple layer structure, the multiple layers of the first insulating layers may include a same insulating material, but are not limited thereto. For example, at least one of the multiple layers of the first insulating layers may include an insulating material different from at least one other first insulating layer.

For example, at least one of the multiple layers of the first insulating layer 111 may include a reinforcing member. In one embodiment, the reinforcing member may mean glass fiber. In another embodiment, the reinforcing member may mean GCP (Glass Core Primer).

In addition, in another embodiment, the multiple layers of the first insulating layer 111 may not include a reinforcing member such as glass fiber and/or GCP.

The insulating layer 110 of the circuit board includes a second insulating layer 112 and a third insulating layer 113.

The second insulating layer 112 may include a same insulating material as the first insulating layer 111. For example, when the first insulating layer 111 of the circuit board is composed of multiple layers, a first insulating layer that is closest to the second insulating layer 112 among the multiple layers of first insulating layers may include a same insulating material as the second insulating layer 112. In this case, an interface between the first insulating layer 111 and the second insulating layer 112 of the circuit board may not be distinguished. Correspondingly, the third insulating layer 113 of the circuit board may include a same insulating material as the first insulating layer 111 of the circuit board.

The second insulating layer 112 and the third insulating layer 113 of the circuit board may each have the function of protecting upper and lower surfaces of the first insulating layer 111 of the circuit board. Accordingly, the second insulating layer 112 and the third insulating layer 113 of the circuit board may be referred to as protective layers. The second insulating layer 112 and the third insulating layer 113 of the circuit board may be solder resist layers including organic polymer materials. For example, the second insulating layer 112 and the third insulating layer 113 of the circuit board may include an epoxy acrylate series resin. In detail, the second insulating layer 112 and the third insulating layer 113 of the circuit board may include a resin, a curing agent, a photoinitiator, a pigment, a solvent, a filler, an additive, an acrylic series monomer, and the like. However, the embodiment is not limited thereto, and the second insulating layer 112 and the third insulating layer 113 of the circuit board may be any one of a photo solder resist layer, a cover-lay, and a polymer material.

The circuit board includes an electrode part. The electrode part includes a first electrode part 120 disposed on a first insulating layer 111. In addition, the first electrode part 120 includes a second electrode part 130 penetrating at least a portion of a region of the first insulating layer 111. The first electrode part 120 may include a pad electrode and/or a trace electrode. In addition, the second electrode part 130 may include a through electrode or a via electrode.

At this time, the first electrode part 120 and the second electrode part 130 may have different arrangement structures depending on a manufacturing method of the circuit board.

For example, referring to FIG. 2, a first electrode part disposed at an uppermost side among the first electrode parts 120 may have a structure protruding on the first insulating layer 111. In addition, the first electrode part disposed at a lowermost side among the first electrode parts 120 may have a structure protruding below the first insulating layer 111. Through this, side surfaces of the first electrode parts respectively positioned at the uppermost and lowermost sides may not come into contact with the first insulating layer 111. For example, the side surfaces of the first electrode parts respectively positioned at the uppermost and lowermost sides may be covered with the second insulating layer 112 or the third insulating layer 113.

Meanwhile, referring to FIG. 3, in another embodiment, at least one of the first electrode parts 120 disposed at the uppermost and lowermost sides may have an ETS (Embedded Trace Substrate) structure. For example, the first electrode part disposed at the uppermost side of the first electrode part 120 may have an ETS structure. For example, a recess may be provided on the upper surface of the first insulating layer 111, and at least a portion of the first electrode part disposed at the uppermost side may be disposed within the recess. For example, at least a portion of a side surface of the first electrode part disposed at the uppermost side may be covered with the first insulating layer 111. The ETS structure may also be referred to as a buried structure. The ETS structure is advantageous for miniaturization compared to an electrode part having a general protruding structure. Accordingly, the embodiment may enable the formation of electrode parts corresponding to a size and pitch of terminals provided in a semiconductor device. Through this, the embodiment may improve the circuit integration. In addition, the embodiment can minimize a transmission distance of a signal transmitted through a semiconductor device, thereby minimizing signal transmission loss.

The first electrode part 120 can be provided on a surface of each of the plurality of layers of the first insulating layer 111. The second electrode part 130 connects the plurality of first electrode parts provided in different layers along the vertical direction. The second electrode part 130 penetrates at least a portion of the region of the first insulating layer 111. The second electrode part 130 can also be called a through electrode or a via electrode.

When the first insulating layer 111 has a five-layer structure, the second electrode part 130 of the electrode part 120 can have a five-layer structure spaced apart from each other along the vertical direction. At this time, the first electrode part 120 can be provided between the second electrode parts 130 of the five-layer structure spaced apart from each other. Hereinafter, a description will be made based on a specific first electrode part 120 disposed on the first insulating layer 111 among the first electrode parts 120 disposed on each of a plurality of planes. For example, the first electrode part described below may refer to the first electrode part disposed at the uppermost side of the circuit board, but is not limited thereto.

The first electrode part 120 includes a pad electrode 121 and a connection electrode 122 depending on the function.

The pad electrode 121 may refer to an electrode vertically overlapping with the second electrode part 130. The pad electrode 121 may refer to an electrode vertically overlapping with a protruding electrode 140 described below. For example, the pad electrode 121 may refer to an electrode vertically overlapping with a semiconductor device disposed on the protruding electrode 140 and/or a terminal of an external substrate. The pad electrodes 121 may be provided in multiple numbers and spaced apart from each other. For example, the pad electrode 121 may include a plurality of pads spaced apart along the horizontal direction.

First, the protruding electrode 140 will be described, and the protruding electrode 140 may be disposed at an uppermost side of the circuit board and may protrude above the circuit board. The protruding electrode 140 may penetrate at least a portion of a region of the second insulating layer 112. The protruding electrode 140 may be provided on the pad electrode 121 of the first electrode part 120 disposed at the uppermost side among the first electrode parts 120. The protruding electrode 140 may be a bump for bonding with a semiconductor device.

The protruding electrode 140 may be positioned higher than the upper surface of the second insulating layer 112. Through this, the embodiment may facilitate a mounting process for bonding a semiconductor device on the protruding electrode 140.

That is, as the width of the terminals of the semiconductor device bonded to the circuit board and the pitch of the terminals are miniaturized, when the semiconductor device is mounted using a conductive adhesive such as solder, diffusion of the conductive adhesive may occur, which may cause a problem in which a plurality of conductive adhesives are connected to each other. Accordingly, the embodiment may perform thermal compression bonding to reduce a volume of the conductive adhesive. Accordingly, the embodiment may be provided with a protruding electrode 140 that protrudes above the circuit board (for example, protrudes above the second insulating layer 112) to secure alignment, diffusion, and diffusion prevention to prevent an intermetallic compound (IMC) formed between the conductive adhesive such as solder and the protrusion from diffusing into the interposer and/or the circuit board. However, the embodiment may perform a bonding process of the semiconductor device in a method other than thermal compression bonding.

A connection electrode 122 may mean an electrode connected to the pad electrode 121. For example, the connection electrode 122 may mean an electrode connected to a pad electrode 121 disposed on a same layer. The connection electrode 122 may be provided to extend long along the horizontal direction. The connection electrode 122 may connect a plurality of pads of the pad electrode 121 along the horizontal direction. An upper surface of the connection electrode 122 may include a width and a length along different horizontal directions. At this time, a width of the connection electrode 122 may be smaller than a length of the connection electrode 122. Therefore, the meaning that the connection electrode 122 extends long along the horizontal direction may be interpreted as the meaning that the length of the upper surface of the connection electrode 122 extends long along the horizontal direction.

That is, each of the plurality of pads of the pad electrode 121 may be connected to the second electrode part 130, and the plurality of pads connected to the second electrode part 130 may be connected through the connection electrode 122. Therefore, the connection electrode 122 can be referred to as a trace.

The pad electrode 121 and the connection electrode 122 of the first electrode part 120 have different widths in the horizontal direction. For example, a planar shape of the pad electrode 121 may be circular. In this case, a width of the pad electrode 121 in the horizontal direction may mean a diameter of the pad electrode 121. In another embodiment, a planar shape of the pad electrode 121 may be an oval shape. When the planar shape of the pad electrode 121 is an oval shape, the width of the pad electrode 121 in the horizontal direction may mean a width in a short axis direction or a width in a long axis direction of the pad electrode 121.

At this time, the pad electrode 121 of the first electrode part 120 of the embodiment may have an oval shape. When the pad electrode 121 has an oval shape, a density of the connection electrode 122 disposed in a limited space can be increased without reducing a contact area between the pad electrode 121 and the protruding electrode 140, and the circuit integration can be improved accordingly. For example, the connection electrode 122 is disposed to extend in one direction between a plurality of pads of the pad electrode 121. For example, as shown in FIG. 4, the connection electrode 122 may have a structure that extends in a first horizontal direction HD1 with a plurality of pads therebetween. At this time, if the pad electrode 121 has a circular shape under the assumption that the planar area of the circular pad electrode and the oval pad electrode is the same, a width of the second horizontal direction HD2 is reduced compared to the case of having an oval shape, but the width of the first horizontal direction HD1 may be increased compared to the case of having an oval shape. Accordingly, when the pad electrodes 121 have a circular shape, the number of lines of the connection electrodes 122 disposed between a plurality of pads spaced apart from each other by the second horizontal direction HD2 may be reduced, and accordingly, a degree of circuit integration may be reduced or an area of the circuit board may be increased. Accordingly, the pad electrode 121 according to an embodiment may have an oval shape.

Referring to FIG. 4, a width W1 of the horizontal direction of the pad electrode 121 can satisfy a range of 20 μm to 80 μm. Preferably, the width W1 of the horizontal direction of the pad electrode 121 can satisfy a range of 30 μm to 70 μm. More preferably, the width W1 of the horizontal direction of the pad electrode 121 can satisfy a range of 35 μm to 65 μm. The width W1 of the horizontal direction of the pad electrode 121 can mean the width of the second horizontal direction HD2 of the pad electrode 121.

If the width W1 of the horizontal direction of the pad electrode 121 is less than 20 μm, the contact area between the pad electrode 121 and the second electrode part 130 and/or the protruding electrode 140 can decrease, which can cause peeling between them. In addition, if the width W1 of the pad electrode 121 in the horizontal direction is less than 20 μm, a volume of a conductive adhesive for bonding with the semiconductor device may decrease, and thus stable electrical and/or physical bonding with the semiconductor device may be difficult. If the width W1 of the pad electrode 121 in the horizontal direction exceeds 80 μm, it may be difficult to place all the pad electrodes 121 connected to the semiconductor device within a limited space. As a result, the area of the circuit board may increase. Furthermore, the transmission distance of a signal exchanged with the semiconductor device may increase, and thus signal transmission loss may increase. Therefore, the semiconductor device may not operate stably, and further, the communication characteristics may deteriorate.

A plurality of pads of the pad electrode 121 may be spaced apart along the first horizontal direction HD1 and/or the second horizontal direction HD2. Referring to FIG. 4, the plurality of pads spaced apart from each other may include a first group overlapping along the second horizontal direction HD2, and a second group spaced apart from the first group along the first horizontal direction. In addition, the plurality of pads included in the second group may overlap along the second horizontal direction HD2. The spaced spaces of the plurality of pads included in the first group in the second horizontal direction HD2 may overlap with the plurality of pads included in the second group along the first horizontal direction HD1. Accordingly, the plurality of pads may be disposed in a zigzag manner so as to increase the integration density.

The plurality of pads of the pad electrode 121 may be spaced apart from each other by a certain spacing in the horizontal direction. For example, a spacing D1 between the pad electrodes 121 spaced apart in the second horizontal direction HD2 may satisfy a range of 15 μm to 35 μm. If the spacing D1 between the pad electrodes 121 is less than 15 μm, the spacing between the connection electrodes 122 disposed between the pad electrodes 121 may decrease, which may cause a short circuit problem in which the plurality of connection electrodes are electrically connected. In addition, if the spacing D1 between the pad electrodes 121 exceeds 35 μm, the circuit integration may decrease accordingly, and further, the area of the circuit board and semiconductor package may increase.

The connection electrode 122 is connected to the pad electrode 121. The connection electrode 122 may be provided in a multiple numbers between the plurality of pads of the pad electrode 121. Here, being provided in multiple numbers may mean that multiple lines of the connection electrode 122 spaced apart from each other are disposed between two adjacent pads.

A width W2 of the connection electrode 122 in the horizontal direction may satisfy a range of 2 μm to 8 μm. Preferably, the width W2 of the horizontal direction of the connection electrode 122 can satisfy a range of 2 μm to 7.5 μm. More preferably, the width W2 of the horizontal direction of the connection electrode 122 can satisfy a range of 2 μm to 5 μm. At this time, the width W2 of the horizontal direction of the connection electrode 122 can mean a horizontal distance between a first side surface and a second side surface, which are opposite to each other, of the connection electrode 122. In addition, referring to FIG. 4, the connection electrode 122 is provided to extend along the first horizontal direction HD1. That is, a length of the first horizontal direction HD1 of the connection electrode 122 is longer than a length of the second horizontal direction HD2, and accordingly, a width of the connection electrode 122 can mean a length of the second horizontal direction HD2 of the connection electrode 122.

In addition, the connection electrode 122 can include a plurality of side surfaces. For example, the connection electrode 122 may include first to fourth side surfaces. The first to fourth side surfaces of the connection electrode 122 extend in a vertical direction from the upper surface of the connection electrode 122 toward the lower surface. At this time, two side surfaces of the first to fourth side surfaces of the connection electrode 122 physically contact different pads. In addition, another two side surfaces of the first to fourth side surfaces of the connection electrode 122 do not physically contact the pads. Therefore, the width W2 of the horizontal direction of the connection electrode 122 may mean a horizontal distance between two side surfaces of the connection electrode 122 that do not physically contact the pads.

If the width W2 of the horizontal direction of the connection electrode 122 is less than 2 μm, the connection electrode 122 may easily collapse or crack due to external impact during the manufacturing process, and thus, the mechanical characteristics and electrical characteristics may deteriorate. In addition, if the width W2 of the horizontal direction of the connection electrode 122 is less than 2 μm, a plating open region that is not plated may be provided in a specific region due to a deviation in the plating process in which the connection electrode 122 is manufactured, and an electrical open problem may occur accordingly. In addition, if the width W2 of the horizontal direction of the connection electrode 122 exceeds 8 μm, it may be difficult to arrange all lines of the connection electrode 122 within a limited space, and thus the circuit integration may be reduced or the area of the circuit board may increase. In addition, if the width W2 of the horizontal direction of the connection electrode 122 exceeds 8 μm, the spacing between the plurality of connection electrodes may become smaller in order to arrange all lines of the connection electrode within a limited space, and thus a short problem in which the plurality of connection electrodes are electrically connected may occur.

Meanwhile, the spacing D2 between the plurality of connection electrodes 122 may satisfy a range of 2 μm to 8 μm. Preferably, the spacing D2 between the plurality of connection electrodes 122 can satisfy a range of 2 μm to 7.5 μm. More preferably, the spacing D2 between the plurality of connection electrodes 122 can satisfy a range of 2 μm to 5 μm.

If the spacing D2 between the plurality of connection electrodes 122 is less than 2 μm, a circuit short problem may occur in which neighboring connection electrodes are electrically connected. If the spacing D2 between the plurality of connection electrodes 122 is less than 2 μm, interference may occur between signals transmitted through the neighboring connection electrodes 122, which may deteriorate the signal transmission characteristics. In addition, if the spacing D2 between the plurality of connection electrodes 122 exceeds 8 μm, it may be difficult to arrange all lines of the connection electrodes 122 within a limited space, and thus, the circuit integration may deteriorate or the area of the circuit board and semiconductor package may increase.

In addition, the connection electrode 122 is provided by being bent at least once in the horizontal direction on the first insulating layer 111.

Specifically, the plurality of pads of the pad electrode 121 on the first insulating layer 111 may not be disposed with uniform spacing along the first horizontal direction HD1 and the second horizontal direction HD2. For example, the plurality of pads of the pad electrode 121 may be provided in a zigzag shape along the first horizontal direction HD1 and/or the second horizontal direction HD2 on the first insulating layer 111. For example, the plurality of pads of the pad electrode 121 may include a plurality of groups that overlap each other in the second horizontal direction HD2. The plurality of groups may be spaced apart from each other in the first horizontal direction HD1. At this time, two adjacent groups may not overlap each other in the first horizontal direction HD1.

For example, when the pads of the first group and the pads of the second group are disposed adjacent to each other, the pads of the first group may be spaced apart from each other in the second horizontal direction HD2, the pads of the second group may be spaced apart from each other in the second horizontal direction HD2, and the pads of the first group and the pads of the second group may not overlap each other while being spaced apart from each other in the first horizontal direction HD1. For example, the pads of the second group may overlap a spaced region between the pads of the first group in the first horizontal direction HD1.

The connection electrode 122 may be disposed between the plurality of pads of the pad electrode 121 disposed in a zigzag manner. The connection electrode 122 may be provided while avoiding arrangement positions of the plurality of pads of the pad electrode 121.

For example, the plurality of pads 121 of the pad electrode 121 may have a width greater than the width of the connection electrode 122. Referring to FIG. 4, among the plurality of pads of the pad electrode 121, the pads that are most adjacent to each other along the second horizontal direction HD2 may be disposed to be misaligned with each other along the first horizontal direction HD1. In addition, the connection electrode 122 may include a first portion 122a extending between the plurality of pads along the first horizontal direction HD1, and a second portion 122b provided between the first portion 122a and having a predetermined inclination with respect to the first horizontal direction HD1 and/or the second horizontal direction HD2. In addition, a region where the first portion 122a and the second portion 122b are connected may be referred to as a bending portion 122c. The connection electrode 122 may include the bending portion 122c in order to be disposed by extending to a spaced region between the plurality of pads of the pad electrode 121, thereby improving the integration of the circuit and reducing the area of the semiconductor package.

The width of the connection electrode 122 may mean a length of the first portion 122a in the second horizontal direction HD2, and the width of the connection electrode 122 may be 2 μm or more and 8 μm or less. As described in the present embodiment, if the width of the connection electrode 122 is small, a problem may occur in which the pattern of the bending portion is not properly formed in the exposure process, or various problems may occur, such as cracks or peeling caused by impact or heat generated during operation of the product, or current concentration due to the fringe field of the electric field. Therefore, a reinforcing pattern 122c1 may be provided in the bending portion 122c to solve the above-described problem. The reinforcing pattern 122c1 may have an effect of widening the width of the connection electrode 122 in the bending portion 122c. Therefore, the problem of the exposure process forming cracks, peeling, and patterns can be relatively solved. However, it is advantageous to form the reinforcing pattern 122c1 small so as not to be related to the change in the overall impedance of the semiconductor substrate.

The reinforcing pattern 122c1 may be provided with a convex shape toward the pad 121. A shortest length of the horizontal direction toward the pad 121 in the bending portion 122c may be longer than the length of the second horizontal direction HD2 between the first portion 122a of the connection electrode and the pad. When the reinforcing pattern 122c1 is provided with a convex shape as described above, the phenomenon of current concentration in the bending portion 122c can be alleviated, thereby having the effect of maintaining the current distribution more evenly. In addition, when the convex shape of the reinforcing pattern 122c1 has a curvature, it can have the advantage of being able to form the pattern more easily in the exposure process for forming the reinforcing pattern 122c1, thereby having the effect of improving the yield.

Specifically, the connection electrode 122 may include a first portion 122a and a second portion 122b that extend in different horizontal directions, respectively. The connection electrode 122 may include a bending portion 122c provided between the first portion 122a and the second portion 122b. In one embodiment, the bending portion 122c may be bent with a specific radius of curvature in the horizontal direction. In another embodiment, the bending portion 122c may be bent with a right angle or a certain obtuse angle. In this case, the first portion 122a and the second portion 122b may be referred to as extended portions of the connection electrode 122, and the bending portion 122c may be referred to as a bent portion of the connection electrode 122. Here, referring to FIG. 6, the first portion 122a may mean a portion extended in the first horizontal direction HD1, and the second portion 122b may mean a portion having a predetermined inclination angle with respect to the first horizontal direction HD1 and/or the second horizontal direction HD2.

For example, the first portion 122a of the connection electrode 122 may extend in the first horizontal direction HD1 on the first insulating layer 111, the second portion 122b of the connection electrode 122 may extend in the second horizontal direction HD2 perpendicular to the first horizontal direction HD1, and the bending portion 122c of the connection electrode 122 may be bent to connect them.

For example, the first portion 122a of the connection electrode 122 may extend in the first horizontal direction HD1 on the first insulating layer 111, the second portion 122b of the connection electrode 122 may extend in a diagonal direction between the first horizontal direction HD1 and the second horizontal direction HD2, and the bending portion 122c of the connection electrode 122 may be bent to connect them.

For example, the first portion 122a of the connection electrode 122 may extend in the second horizontal direction HD2 on the first insulating layer 111, and the second portion 122b of the connection electrode 122 may extend in a diagonal direction between the first horizontal direction HD1 and the second horizontal direction HD2, and the bending portion 122c of the connection electrode 122 may be bent to connect them.

For example, the first portion 122a of the connection electrode 122 may extend in a first diagonal direction between the first horizontal direction HD1 and the second horizontal direction HD2 on the first insulating layer 111, the second portion 122b of the connection electrode 122 may extend in a second diagonal direction between the first horizontal direction HD1 and the second horizontal direction HD2, and the bending portion 122c of the connection electrode 122 may be bent to connect them.

Therefore, the integration of the connection electrode 122 can be improved through the bending portion 122c, so that the electrical length of the connection electrode 122 can be shortened, and the overall impedance of the connection electrode 122 can be efficiently improved by reducing parasitic capacitance, parasitic inductance, parasitic resistance, etc., and there is an advantage of miniaturizing the area of the semiconductor package.

At this time, the connection electrode 122 may be a fine pattern. As described, the width W2 of the connection electrode 122 may be 8 μm or less, 6 μm or less, 5 μm or less, or 4 μm or less. As a result, the electrical reliability and/or physical reliability of the bending portion 122c of the connection electrode 122 may be deteriorated.

For example, if the connection electrode 122 has a width exceeding 8 μm, the electrical reliability and/or physical reliability problems may not occur at the bending portion. However, there may be a problem that it is difficult to miniaturize the area of the semiconductor package, and there may be a problem that it is difficult to efficiently improve the overall impedance of the connection electrode 122.

If the connection electrode 122 is a fine pattern having a width of 8 μm or less, plating may not be smoothly performed at the bending portion 122c of the connection electrode 122 depending on the plating process capability in the manufacturing process for manufacturing the connection electrode 122. For example, a dry film may be disposed on the first insulating layer 111, and the dry film may have an opening corresponding to the connection electrode 122 through exposure and development. At this time, due to the characteristics of the exposure and development process of the dry film, an exposure resolution and/or a development resolution in the region corresponding to the bending portion may be deteriorated. As a result, development may not be performed in a region corresponding to the bending portion of the dry film, or development may be performed with a value smaller than a target value. As a result, an electrical open problem may occur due to the connection electrode 122 not being plated in the bent portion of the connection electrode. Furthermore, even if the electrical open problem does not occur, stress due to an external impact may be concentrated at the bent portion, and the connection electrode 122 may collapse or crack due to the stress. In addition, the width of the horizontal direction of the connection electrode 122 in the bending portion may be reduced, and as a result, the impedance matching characteristic affected by the length, width, and thickness of the connection electrode 122 may be reduced. This may cause difficulties in impedance matching of the circuit board and the semiconductor package.

Accordingly, the embodiment provides a reinforcing pattern 122c1 in the bending portion 122c of the connection electrode 122. The reinforcing pattern 122c1 may mean a step whose width changes in the bending portion 122c of the connection electrode 122. Preferably, the reinforcing pattern 122c1 may mean a step in the horizontal direction whose width increases in the bending portion 122c of the connection electrode 122 or a step at a side surface of the connection electrode 122.

That is, the bending portion 122c of the connection electrode 122 may be provided with a reinforcing pattern 122c1, and through this, the electrical characteristics and physical characteristics of the bending portion 122c of the connection electrode 122 may be improved. For example, the embodiment may provide a reinforcing pattern 122c1 in the bending portion 122c of the connection electrode 122 to increase the rigidity of the connection electrode 122, thereby solving a problem of the connection electrode 122 collapsing or cracking. Furthermore, the embodiment may provide a reinforcing pattern 122c1 to be provided in the bending portion 122c of the connection electrode 122, thereby making the reinforcing pattern 122c1 have a width greater than the width of the first portion 122a and/or the second portion 122b adjacent to the reinforcing pattern. Accordingly, the embodiment may solve an electrical open problem occurring in the bending portion 122c of the connection electrode 122, thereby improving electrical reliability.

For example, the bending portion 122c of the connection electrode 122 may mean a boundary region between the first portion 122a and the second portion 122b of the connection electrode 122. The width of the bending portion 122c of the connection electrode 122 in the horizontal direction may be larger than the width of the first portion 122a in the horizontal direction and/or the width of the second portion 122b in the horizontal direction. For example, the bending portion 122c of the connection electrode 122 may include a first side surface 122cs1 and a second side surface 122cs2 facing each other. At least one of the first side surface 122cs1 and the second side surface 122cs2 of the bending portion 122c of the connection electrode 122 has a convex portion that is convex in an outward direction and corresponds to a reinforcing pattern 122c1. The width in the horizontal direction of the bending portion 122c of the connection electrode 122 may be larger than the width in the horizontal direction of the first portion 122a and/or the second portion 122b by a convex horizontal distance from the convex portion.

Meanwhile, the reinforcing pattern 122c1 may be provided on both the first side surface 122cs1 and the second side surface 122cs2 of the bending portion 122c, but may be provided on only one of the first side surface 122cs1 and the second side surface 122cs2 in another embodiment. In this case, when the reinforcing pattern 122c1 is provided on only one of the first side surface 122cs1 and the second side surface 122cs2, the reinforcing pattern 122c1 may be provided on a side surface having a relatively shorter length among the first side surface 122cs1 and the second side surface 122cs2. For example, the side surface of the bending portion 122c may be divided into an inner side surface and an outer side surface depending on a bending direction. For example, in a right enlarged view of FIG. 4, the first side surface 122cs1 may be an inner side surface, and the second side surface 122cs2 may be an outer side surface. In the case where the bending portion 122c is provided as such, a portion corresponding to the first side surface 122cs1 may be relatively weaker to impact than a portion corresponding to the second side surface 122cs2. Therefore, in the embodiment, when the reinforcing pattern 122c1 is provided on only one side of the first side surface 122cs1 and the second side surface 122cs2, the reinforcing pattern is provided on the first side surface 122cs1 of the bending portion 122c corresponding to the inner side surface, thereby improving the rigidity of the bending portion 122c.

Furthermore, in the embodiment, by providing the reinforcing pattern 122c1 on the bending portion 122c, the bending portion 122c can have a width in the horizontal direction that is targeted, thereby improving the impedance characteristics determined by the width, length, and thickness of the connection electrode 122. In other words, the embodiment can make the impedance characteristics match a design value, and can smoothly perform the impedance matching accordingly, so that the impedance control can be facilitated.

Furthermore, the embodiment can increase a contact area with the insulating layer 110 by an area of the reinforcing pattern 122c1 by providing a reinforcing pattern 122c1 corresponding to the convex portion on the side surface of the connection electrode 122. Through this, the embodiment can improve the adhesion between the connection electrode 122 and the insulating layer 110, and can solve the problem of the connection electrode 122 being peeled off from the insulating layer 110. For example, the reinforcing pattern 122c1 can overlap with the insulating layer 110 in the vertical direction and/or the horizontal direction, and through this, a bonding strength in the vertical direction and/or a bonding strength in the horizontal direction between the connection electrode 122 and the insulating layer 110 can be strengthened. In addition, when each layer of the insulating layer 110 is provided with different insulating materials, peeling in the vertical direction and/or horizontal direction may occur due to different coefficients of thermal expansion between different materials. In addition to the function of improving the rigidity of the connection electrode 122, the reinforcing pattern 122c1 may also have the function of increasing the contact area with the insulating layer 110, thereby strengthening the bonding strength between them.

Meanwhile, referring to FIG. 5, the connection electrode 122 of the embodiment may have a plurality of bending portions, and the reinforcing pattern 122c1 may be provided only on a specific bending portion among the plurality of bending portions.

The connection electrode 122 may have a fine width W2 in a range described above.

However, the connection electrode 122 may have different widths for each region on the first insulating layer 111.

That is, the connection electrode 122 may include a region requiring a fine width and a region not requiring a fine width in an entire region on the first insulating layer 111.

A reinforcing pattern 122c1 may be provided in the bending portion of the connection electrode 122 provided in the region requiring a fine width. In addition, a reinforcing pattern 122c1 may be provided in the bending portion of the connection electrode 122 provided in the region not requiring a fine width.

For example, the connection electrode 122 may be provided in a plurality of regions. The plurality of regions may include a first region, a second region, and a third region.

The first region may be a region requiring a fine width of the connection electrode 122, and the second and third regions may be regions not requiring a fine width of the connection electrode 122.

The connection electrode 122 may include a first connection electrode 122-1 provided in the first region, a second connection electrode 122-2 provided in the second region, and a third connection electrode 122-3 provided in the third region.

The first connection electrode 122-1 may have a width W2 in a range of 2 μm to 8 μm. For example, the first connection electrode 122-1 may be provided as a plurality of lines between a plurality of pads of the pad electrode 121. The number of lines of the first connection electrode 122-1 provided in the first region may be greater than the number of lines of the second connection electrode 122-2 provided in the second region. Accordingly, each line of the first connection electrode 122-1 provided in the first region may require a finer line width than the second connection electrode 122-2 provided in the second region for integration.

For example, the pads of the pad electrode 121 may include a first pad and a second pad, and three lines of first connection electrodes 122-1 may be provided between the first pad and the second pad. At this time, a spacing D1 between the first pad and the second pad may be same as the described range, and in order to place three lines of first connection electrodes 122-1 within the spacing D1, a fine width of the first connection electrode 122 may be required. Accordingly, a reinforcing pattern 122c1 having a step whose width changes in the horizontal direction may be provided in the bending portion 122c of the first connection electrode 122 provided in the first region.

In addition, each of the second connection electrode 122-2 and the third connection electrode 122-3 may have a width W3 larger than that of the first connection electrode 122-1. The width W3 of the second connection electrode 122-2 and the third connection electrode 122-3 can satisfy a range of 130% to 250% of the width W2 of the first connection electrode 122-1.

Specifically, the pads of the pad electrode 121 can include a third pad and a fourth pad, and a second connection electrode 122-2 having a smaller number of lines than the first connection electrode 122-1 can be provided between the third pad and the fourth pad. For example, the number of lines of the second connection electrode 122-2 can be 2 or less.

At this time, the spacing between the third pad and the fourth pad can be the same as the spacing between the first pad and the second pad. Two lines of second connection electrodes 122-2 may be disposed between the third pad and the fourth pad, and accordingly, a width W3 in the horizontal direction of the second connection electrode 122-2 may be larger than a width in the horizontal direction of the first connection electrode 122-1. Furthermore, since the second connection electrode 122-2 has a relatively large horizontal width compared to the first connection electrode 122-1, the rigidity of the second connection electrode may be maintained even without a reinforcing pattern 122c1 in the bending portion. Accordingly, the reinforcing pattern 122c1 may not be provided in the bending portion of the second connection electrode 122-2.

In addition, the third connection electrode 122-3 may include a plurality of lines, and a pad electrode 121 may not be provided between the third connection electrodes 122-3. Accordingly, an unit area occupied by each line of the third connection electrode 122-3 in the third region may be larger than an area occupied by each line of the first connection electrode 122-1 in the first region. Accordingly, the third connection electrode 122-3 may not require a fine width, and thus may have a relatively larger width W3 than the first connection electrode 122-1. Due to this, the bending portion of the third connection electrode 122-3 may not be provided with a reinforcing pattern 122c1.

Meanwhile, referring to FIG. 6, the connection electrode 122 of the embodiment may include a reinforcing pattern 122c1. The reinforcing pattern 122c1 may be a convex portion provided in the bending portion 122c of the connection electrode 122. Hereinafter, the reinforcing pattern 122c1 is described as a convex portion.

The first side surface 122c1 of the bending portion 122c of the connection electrode 122 may include a convex portion 122c1 that protrudes or is convex toward the outside. Through this, a first portion 122a, a second portion 122b of the connection electrode 122, and a first side surface of the bending portion 122c may have a step based on the convex portion 122c1.

The second side surface 122cs2 of the bending portion 122c of the connection electrode 122 may include a concave portion 122c2 that is concave toward the inside. For example, in a region where the concave portion 122c2 of the connection electrode 122 is located, the width of the connection electrode 122 can be reduced, and accordingly, the impedance of the connection electrode 122 can be efficiently improved, thereby improving the overall electrical characteristics of the connection electrode 122.

For example, the concave portion 122c2 can minimize the difference in the width of each portion of the connection electrode 122, thereby improving the electrical characteristics.

For example, the concave portion 122c2 can minimize the difference in the width in the horizontal direction between the first portion 122a and/or the second portion 122b of the connection electrode 122 and the bending portion 122c. Through this, the embodiment can minimize signal transmission loss that may occur due to a difference in width between the first portion 122a and/or the second portion 122b of the bending portion 122c and the bending portion 122c, and further, can enable the semiconductor device to operate smoothly.

In addition, the concave portion 122c2 can control the impedance characteristic that changes by the convex portion 122c1 provided in the bending portion 122c of the connection electrode 122. For example, an impedance state formed by the connection electrode 122 can change by a protruding length or convex length of the convex portion 122c1. Therefore, the embodiment provides the concave portion 122c2 on an opposite side surface of the convex portion 122c1 of the bending portion 122c. Through this, the embodiment can minimize the change in impedance characteristics and further improve the ease of impedance control.

In addition, the concave portion 122c2 can function to increase the contact area between the insulating layer 110 and the connection electrode 122 together with the convex portion 122c1. Through this, the embodiment can further strengthen the bonding force between the connection electrode 122 and the insulating layer 110.

Meanwhile, referring to FIG. 7, the concave portion 122c2 may be provided on the first portion 122a and/or the second portion 122b of the connection electrode 122 rather than the bending portion 122c.

In one embodiment, the concave portion 122c2 may be provided on the first portion 122a of the connection electrode 122. In another embodiment, the concave portion 122c2 may be provided on the first portion 122a adjacent to the bending portion 122c of the connection electrode 122. In another embodiment, the concave portion 122c2 may be provided on each of the first portion 122a and the second portion 122b of the connection electrode 122.

At this time, the concave portion 122c2 may be provided on an opposite side surface of a side surface on which the convex portion 122c1 of the bending portion 122c is provided, among the side surfaces of the first portion 122a of the connection electrode 122. For example, the convex portion 122c1 may be provided on the first side surface 122c1 of the bending portion 122c. In this case, the concave portion 122c2 may be provided on the second side surface of the first portion 122a.

For example, the concave portion 122c2 may be provided on the second portion 122b adjacent to the bending portion 122c of the connection electrode 122. At this time, the concave portion 122c2 may be provided on an opposite side surface of a side surface on which the convex portion 122c1 of the bending portion 122c2 is provided, among the side surfaces of the second portion 122b of the connection electrode 122. For example, the convex portion 122c1 may be provided on the first side surface 122c1 of the bending portion 122c. In this case, the concave portion 122c2 may be provided on the second side surface of the second portion 122b.

Through this, the embodiment can improve the impedance matching characteristics of the circuit board and the semiconductor package. In addition, the embodiment can alleviate the electrical characteristics that change through the protrusion 122c1 by using the concave portion 122c2. In addition, the embodiment can strengthen the bonding strength with the insulating layer 110 by using the concave portion 122c2.

Meanwhile, referring to FIG. 8, the convex portion 122c1 can be provided on different side surfaces of each electrode line of the connection electrode 122.

For example, the connection electrode 122 can include three electrode lines disposed between the first pad and the second pad of the pad electrode 121. For example, the connection electrode 122 can include a first electrode line 122L1 adjacent to the first pad. For example, the connection electrode 122 can include a second electrode line 122L2 adjacent to the second pad. For example, the connection electrode 122 may include a third electrode line 122L3 disposed between the first electrode line 122L1 and the second electrode line 122L2.

Each of the first electrode line 122L1 and the second electrode line 122L2 may have a convex portion.

At this time, the first electrode line 122L1 may include a first side surface facing a side surface of an adjacent pad electrode 121 and a second side surface opposite to the first side surface and facing a side surface of an adjacent electrode line (e.g., the third electrode line 122L3). The convex portion in the first electrode line 122L1 may be provided on the first side surface facing the side surface of the pad electrode 121. In addition, the convex portion provided in the third electrode line 122L3 may be provided on the side surface facing the pad electrode 121.

Through this, when each of the neighboring electrode lines is provided with a convex portion, the embodiment can solve the problem of a circuit short circuit caused by a reduction in the spacing between the neighboring electrode lines due to the convex portion.

Meanwhile, referring to FIG. 9, the connection electrode 122 of the electrode part 120 of the embodiment may further include a connection portion 122d connected to the pad electrode 121.

The connection portion 122d of the connection electrode 122 may mean a portion of an entire region of the connection electrode 122 that comes into contact with the pad electrode 121.

The connection portion 122d may be connected to the pad electrode 121. The connection portion 122d may connect between the pad electrode 121 and the first portion 122a and/or the second portion 122b of the connection electrode 122.

The connection portion 122d may include a region whose width changes. For example, the connection portion 122d may include one end in contact with the pad electrode 121. In addition, a width of the one end of the connection portion 122d in the horizontal direction may be smaller than the width W1 of the pad electrode 121 in the horizontal direction and larger than the width of at least one of the first portion 122a, the second portion 122b, and the bending portion 122c of the connection electrode 122.

In addition, the connection portion 122d may include a region whose width gradually decreases as it moves from the pad electrode 121 toward the first portion 122a, the second portion 122b, and the bending portion 122c of the connection electrode 122.

That is, the embodiment may not have the entire region of the connection electrode 122 have the width W2 or W3 as described, but may have the connection portion 122d so that the width gradually decreases.

Through this, the embodiment can improve communication characteristics by minimizing signal transmission loss that occurs as the width between the pad electrode 121 and the connection electrode 122 is rapidly reduced.

Meanwhile, referring to FIG. 10, the pad electrode 121 of the embodiment may have a planar shape that is deformed into a shape other than an oval shape.

For example, the pad electrode 121 may include a curve portion 121-1, a first straight portion 121-2, and a second straight portion 121-3 based on a perimeter of an upper surface.

For example, the pad electrode 121 may include a curve portion 121-1 having a specific radius of curvature. The radius of curvature of the curve portion 121-1 of the pad electrode 121 may be determined based on the width W1 of the pad electrode 121 in the horizontal direction.

The pad electrode 121 may include a first straight portion 121-2 connected to the curve portion 121-1. The first straight portion 121-2 may be connected to both ends of the curve portion 121-1. Accordingly, the first straight portion 121-2 may include a first line connected to one end of the curve portion 121-1 and a second line connected to the other end of the curve portion 121-1.

At this time, when the pad electrode 121 has an oval shape, a second curve portion having a radius of curvature corresponding to the first straight portion may be disposed at the ends of the first and second lines of the first straight portion 121-2.

Alternatively, the embodiment may include a second straight portion 121-3 bent from ends of the first and second lines of the first straight portion 121-2. The second straight portion 121-3 may extend in a direction different from a direction in which the first straight portion 121-2 extends.

For example, the second straight portion 121-3 may be bent from the first straight portion 121-2 in a direction corresponding to the connection electrode 122 adjacent thereto.

For example, the second straight portion 121-3 may be bent from the first straight portion 121-2 in a direction corresponding to the bending direction of the bending portion 122c of the connection electrode 122. Through this, since the embodiment includes the second straight portion 121-3, a spacing between the bending portion 122c of the connection electrode 122 adjacent to the second straight portion 121-3 and the pad electrode 121 can be increased. Accordingly, even if the bending portion 122c is provided with the convex portion 122c1, the embodiment can solve a short circuit problem in which the connection electrode 122 and the pad electrode 121 are electrically connected to each other by the convex portion 122c1.

The circuit board of the embodiment and the semiconductor package including the same include an electrode part. At this time, an upper surface of the electrode part includes a first portion extended along a first horizontal direction, a second portion extended along a second horizontal direction having a predetermined incline with the first horizontal direction, and a bending portion provided between the first portion and the second portion. At this time, the bending portion includes a reinforcing pattern. The reinforcing pattern can have a function of increasing a width of the bending portion of the electrode part.

The reinforcing pattern is provided with a convex shape toward an adjacent pad. Accordingly, the embodiment can provide the reinforcing pattern with a convex shape, thereby alleviating a phenomenon of current concentration in the bending portion. Accordingly, the embodiment can maintain the current distribution of the electrode part more evenly. In addition, when the convex shape of the reinforcing pattern has a curvature, a pattern can be formed more easily in an exposure process for forming the reinforcing pattern, thereby improving the product yield.

Furthermore, the embodiment can provide a reinforcing pattern in the bending portion, thereby improving a weak rigidity in the bending portion of the electrode part. Therefore, the embodiment can solve an electrical open or crack problem occurring in the bending portion of the electrode part, thereby improving the electrical reliability and/or physical reliability of the semiconductor package. In addition, the embodiment can enable a semiconductor device provided in the semiconductor package to operate smoothly, thereby improving the operational reliability of an electronic product such as a server to which the semiconductor package is applied.

In addition, the electrode part of the embodiment can include a bending portion, thereby improving the integration degree of the electrode part, and shortening an electrical length of the electrode part. Therefore, the embodiment can reduce parasitic capacitance, parasitic inductance, parasitic resistance, etc. of the electrode part, thereby efficiently improving the overall impedance of the electrode part, and further miniaturizing an area of the semiconductor package.

In addition, the electrode part of the embodiment has first and second side surfaces. In addition, the first side surface of the electrode part may be provided with a convex portion of a reinforcing pattern, and the second side surface may be provided with a concave portion. The concave portion may be provided concavely from the second side surface of the electrode part toward the first side surface. The concave portion may alleviate electrical characteristics of the electrode part that change due to the convex portion. Through this, the embodiment may further improve the electrical reliability of the electrode part. For example, the electrode part of the embodiment may have a reduced width in a region including the concave portion. Through this, the embodiment may efficiently improve an impedance of the electrode part, and through this, may function to improve the overall electrical characteristics of the electrode part.

In addition, the electrode part of the embodiment may be provided with a concave portion and a convex portion, and through this, a contact area between the insulating layer and the electrode part may be increased. Through this, the embodiment may improve an adhesion between the electrode part and the insulating layer, and may solve a problem of the electrode part being peeled off from the insulating layer. For example, the concave portion and/or the convex portion of the electrode part may overlap with the insulating layer in a vertical direction and/or a horizontal direction, thereby strengthening a bonding strength in the vertical direction and/or a bonding strength in the horizontal direction between the electrode part and the insulating layer. Furthermore, when each layer of the insulating layer is formed of a different insulating material, peeling in the vertical direction and/or the horizontal direction may occur due to different coefficients of thermal expansion between the different materials. Therefore, the embodiment can improve the electrical reliability of the electrode part by using the concave portion and the convex portion, while improving the mechanical reliability by increasing a contact area with the insulating layer.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating layer; and
an electrode part disposed on the insulating layer,
wherein the electrode part includes a plurality of pad electrodes, and a plurality of connection electrodes connecting between the plurality of pad electrodes and heaving a width smaller than widths of the plurality of pad electrodes,
wherein the plurality of connection electrodes include a first portion extending along a first direction parallel to an upper surface of the insulating layer, a second portion extending from the first portion along a second direction parallel to an upper surface of the insulating layer and having a predetermined inclination angle with respect to the first direction, and a bending portion provided between the first portion and the second portion, and
wherein the bending includes a reinforcing pattern provided on one surface facing an outer surface of at least one pad electrode among the plurality of pad electrodes.

2. The circuit board of claim 1, wherein the electrode part has a step whose width changes in the bending portion between the first portion and the second portion.

3. The circuit board of claim 1, wherein a width of the bending portion including the reinforcing pattern is larger than a width of at least one of the first portion and the second portion.

4. The circuit board of claim 1, wherein the electrode part has a width in a range of 2 μm to 8 μm.

5. The circuit board of claim 1, wherein the bending portion further includes a reinforcing pattern in a region where an extension line of the first portion and an extension line of the second portion form an obtuse angle.

6. The circuit board of claim 1, wherein the plurality of pad electrodes have a width in a range of 20 μm to 80 μm.

7. The circuit board of claim 1, wherein the reinforcing pattern is a convex portion convex toward an outside of the bending portion.

8. The circuit board of claim 1, wherein the bending portion further includes a first concave portion that is concave toward an inside of the bending portion and provided on another surface opposite to the one surface.

9. The circuit board of claim 1, wherein at least one side surface of the first and second portions of the plurality of connection electrodes is provided with a second concave portion that is concave toward an inside of the plurality of connection electrodes.

10. The circuit board of claim 1, wherein the electrode part includes a first group of connection electrode parts including a plurality of electrode lines spaced apart from each other with a first spacing, and a second group of connection electrode parts including a plurality of electrode lines spaced apart from each other with a second spacing larger than the first spacing,
wherein the bending portion of the connection electrode part of the first group is provided with the reinforcing pattern, and
wherein the bending portion of the connection electrode part of the second group is not provided with the reinforcing pattern.

11. The circuit board of claim 1, wherein the plurality of connection electrodes include a connection portion provided between the plurality of pad electrodes and the first portion or the second portion, and
wherein the connection portion has a width that changes from the plurality of pad electrodes toward the first portion or the second portion.

12. The circuit board of claim 11, wherein the connection portion has a width that gradually decreases from the plurality of pad electrodes toward the first portion or the second portion.

13. The circuit board of claim 1, wherein a planar shape of the plurality of pad electrodes has an oval shape.

14. The circuit board of claim 1, wherein a perimeter of an upper surface of the plurality of pad electrodes include:
a curved portion having a specific radius of curvature;
a first straight portion connected to the curved portion; and
a second straight portion extending along a horizontal direction with a predetermined incline from the first straight portion.

15. The circuit board of claim 10, wherein a width of the first portion or the second portion of the connection electrode part of the first group is smaller than a width of the first portion or the second portion of the connection electrode part of the second group.

16. A circuit board of comprising:
an insulating layer; and
an electrode part disposed on the insulating layer,
wherein the electrode part includes a plurality of pad electrodes, and a plurality of connection electrodes connecting between the plurality of pad electrodes and having a width smaller than widths of the plurality of pad electrodes,
wherein the plurality of connection electrodes include a first portion extending along a first direction parallel to an upper surface of the insulating layer, a second portion extending from the first portion along a second direction parallel to the upper surface of the insulating layer and having a predetermined incline with respect to the first direction, and a bending portion provided between the first part and the second part,
wherein the plurality of pad electrodes include a first group of pad parts including a plurality of pad electrodes spaced apart from each other in a third direction parallel to the upper surface of the insulating layer and perpendicular to the first direction; and a second group of pad parts including a plurality of pad electrodes spaced apart from the pad part of the first group in the first direction and spaced apart from each other in the third direction, and
wherein the plurality of connection electrodes are provided with a reinforcing pattern in the bending portion overlapping the pad portion of the second group in the third direction.

17. The circuit board of claim 16, wherein the plurality of connection electrodes are provided with a width of the first portion or the second portion overlapping the pad portion of the second group in the third direction smaller than a width of the first portion or the second portion overlapping the pad portion of the first group in the third direction.

18. The circuit board of claim 16, wherein the bending portion is provided on one side surface facing the pad portion of the second group.

19. The circuit board of claim 16, wherein a number of connection electrodes disposed between the plurality of electrode pads of the pad portion of the first group is less than a number of connection electrodes disposed between the plurality of electrode pads of the pad portion of the second group.

20. The circuit board of claim 16, wherein at least one side surface of the plurality of connection electrodes includes a concave portion concave toward an inside of the plurality of connection electrodes.
